(19) United States
(12) Patent Application Publication
(10) Pub. No.: US 2026/0362929 A1
(43) Pub. Date: Nov. 12, 2026

(54) DISPLAY DEVICE, METHOD OF MANUFACTURING THE SAME AND ELECTRONIC DEVICE INCLUDING SAME

(71) Applicant: Samsung Display Co., Ltd., Yongin-si (KR)

(72) Inventors: Ji Seong YANG, Yongin-si (KR); Jeong Hwan KIM, Yongin-si (KR); DOHYUN JUNG, Yongin-si (KR)

(21) Appl. No.: 19/544,495

(22) Filed: Feb. 19, 2026

(30) Foreign Application Priority Data
Mar. 12, 2025 (KR) 10-2025-0032112

(51) Int. Cl. H10K 59/38; H10K 59/12; H10K 59/122; H10K 59/80

(52) U.S. Cl. CPC H10K 59/38; H10K 59/1201; H10K 59/122; H10K 59/873; H10K 59/8792

(57) ABSTRACT

A display device includes a substrate, a first light emitting element and a second light emitting element disposed on the substrate and adjacent to each other, an encapsulation layer disposed on the first light emitting element and the second light emitting element, a bank disposed on the encapsulation layer and defining therein a first opening and a second opening overlapping the first light emitting element and the second light emitting element, respectively, a first color converting layer and a second color converting layer disposed on the encapsulation layer and disposed in the first opening and the second opening, respectively, and a metal layer disposed on the bank. The bank includes a first sub-bank and a second sub-bank separated from each other between the first color converting layer and the second color inverting layer, and the metal layer includes a portion disposed between the first sub-bank and the second sub-bank.

This application claims priority to Korean Patent Application No. 10-2025-0032112, filed on Mar. 12, 2025, and all the benefits accruing therefrom under 35 U.S.C. § 119, the content of which in its entirety is herein incorporated by reference.

### BACKGROUND

### 1. Field

The present disclosure relates to a display device, a manufacturing method thereof, and an electronic device including the same.

### 2. Description of the Related Art

Emissive display devices displaying images by controlling the luminance of light-emitting elements and liquid crystal displays displaying images by controlling the transmittance of a liquid crystal layer are widely used as display devices. Unlike liquid crystal displays, an emissive display device does not require a separate light source such as a backlight, so the thickness and weight of the display device may be reduced. In addition, an emissive display device may exhibit high-quality characteristics such as low power consumption, high luminance, and high reaction speed.

An emissive display device may include a display area corresponding to a screen displaying an image, and pixels may be arranged in the display area. The pixels may be implemented by light emitting diodes. A light emitting diode may include a light emitting layer positioned between two electrodes. One of the two electrodes may be a pixel electrode provided individually for each pixel, and the other may be a common electrode provided in common to a plurality of pixels. Additionally, an emissive display device may include a color converting layer to change the wavelength of light provided by the light emitting element.

### SUMMARY

The embodiments attempt to provide a display device with improved optical efficiency.

The embodiments attempt to provide a display device manufacturing method with improved process efficiency.

The embodiments attempt to provide an electronic device including a display device having improved resolution.

A display device according to an embodiment includes a substrate, a first light emitting element and a second light emitting element disposed on the substrate and adjacent to each other, an encapsulation layer disposed on the first light emitting element and the second light emitting element, a bank disposed on the encapsulation layer and defining therein a first opening and a second opening overlapping the first light emitting element and the second light emitting element, respectively, in a plan view, a first color converting layer and a second color converting layer disposed on the encapsulation layer and disposed in the first opening and the second opening respectively, and a metal layer disposed on the bank. The bank includes a first sub-bank and a second sub-bank, which are separated from each other and disposed between the first color converting layer and the second color converting layer, and the metal layer includes a portion disposed between the first sub-bank and the second sub-bank.

The first sub-bank may surround the first color converting layer in the plan view, and the second sub-bank may be spaced apart from the first sub-bank and surround the second color converting layer in the plan view.

The metal layer may cover the first sub-bank and the second sub-bank, and may fill at least a portion of a space between the first sub-bank and the second sub-bank.

The display device may further include an anti-reflection layer disposed on the metal layer, and the anti-reflection layer may cover the entirety of the metal layer.

The metal layer may include a first sub-metal layer and a second sub-metal layer, which cover the first sub-bank and the second sub-bank, respectively, and are spaced apart from each other between the first sub-bank and the second sub-bank.

The display device may further include an anti-reflection layer disposed on the metal layer, the anti-reflection layer may cover the entirety of the metal layer and may fill at least a portion of a space between the first sub-metal layer and the second sub-metal layer.

The display device may further include an anti-reflection layer disposed on the metal layer, and the metal layer may partially cover the first color converting layer and the second color converting layer.

The anti-reflection layer may cover an upper surface and a side surface of the metal layer, and may partially cover the first color converting layer and the second color converting layer.

The anti-reflection layer may cover an upper surface of the metal layer and may not cover a side surface of the metal layer.

The display device may further include a capping layer disposed between the bank and the metal layer, and a color filter layer disposed on the bank, the first color converting layer, and the second color converting layer.

The capping layer may cover the first color converting layer and the second color converting layer.

An electronic device according to an embodiment includes an electronic component and a display device. The display device includes a substrate, a first light emitting element and a second light emitting element disposed on the substrate and adjacent to each other, a bank disposed on the first light emitting element and the second light emitting element and defining therein a first opening and a second opening overlapping the first light emitting element and the second light emitting element, respectively, in a plan view, a first color converting layer and a second color converting layer disposed on the first light emitting element and the second light emitting element and disposed within the first opening and the second opening respectively, and a metal layer disposed on the bank. The bank includes a first sub-bank and a second sub-bank, which are separated from each other and disposed between the first color converting layer and the second color converting layer, and the metal layer is disposed between the first sub-bank and the second sub-bank.

The first sub-bank may surround the first color converting layer in the plan view, the second sub-bank may be spaced apart from the first sub-bank and surround the second color converting layer in the plan view, and the metal layer may cover the first sub-bank and the second sub-bank and fill at least a portion of a space between the first sub-bank and the second sub-bank.

The first sub-bank may surround the first color converting layer in the plan view, the second sub-bank may be spaced apart from the first sub-bank and surround the second color converting layer in the plan view, and the metal layer may include a first sub-metal layer and a second sub-metal layer, which cover the first sub-bank and the second sub-bank, respectively, and are spaced apart from each other between the first sub-bank and the second sub-bank.

A display device manufacturing method according to an embodiment includes forming a first light emitting element and a second light emitting element adjacent to each other on a substrate, forming an encapsulation layer on the first light emitting element and the second light emitting element, forming a bank including a first sub-bank defining therein a first opening overlapping the first light emitting element and a second sub-bank separated from the first sub-bank and defining therein a second opening overlapping the second light emitting element in a plan view, forming a first color converting layer and a second color converting layer disposed in the first opening and the second opening, respectively, forming a metal layer disposed on the bank and disposed between the first sub-bank and the second sub-bank, and forming an anti-reflection layer on the metal layer.

The bank may be formed through a first mask, the metal layer may be formed through a second mask, and the anti-reflection layer may be formed through a third mask.

The second mask and the third mask may be the same mask.

The metal layer may fill at least a portion of a space between the first sub-bank and the second sub-bank.

The metal layer may include a first sub-metal layer and a second sub-metal layer, which cover the first sub-bank and the second sub-bank, respectively, and are spaced apart from each other between the first sub-bank and the second sub-bank.

The display device manufacturing method may further include forming a capping layer on the bank and the color converting layer.

According to an embodiment, when light passes through the color converting layer, a part of the light may pass through the bank and the like surrounding the color converting layer along the path of the light. In this case, it is possible to suppress that light is randomly reflected by the bank and the like not to be emitted to the outside, or the light is absorbed by banks and the like, as light passes through banks, etc. Therefore, the light quantity emitted through the color converting layer may increase. Accordingly, optical efficiency may be effectively improved.

According to the embodiments, the number of masks required for manufacturing a color converting layer may be reduced. Accordingly, process efficiency may be improved, and process costs may be effectively reduced.

According to the embodiments, the electronic device may include a display device with improved optical efficiency. Additionally, the resolution of the screen displayed on the electronic device may be improved because the region where light is not emitted may be effectively reduced.

### BRIEF DESCRIPTION OF THE DRAWINGS

FIG. 1 is a schematic top plan view of a display device according to an embodiment.

FIG. 2 is a schematic top plan view of a region corresponding to approximately six pixels of a display device according to an embodiment.

FIG. 3 is a schematic cross-sectional view of a region corresponding to approximately three pixels of a display device according to an embodiment.

FIG. 4 is a schematic cross-sectional view of a part of a color converting layer and a part of an insulation layer included in a display device according to an embodiment.

FIG. 5 is a schematic cross-sectional view of a region corresponding to approximately three pixels of a display device according to another embodiment.

FIG. 6 is a schematic cross-sectional view of a part of a color converting layer and a part of an insulation layer included in a display device according to an embodiment.

FIGS. 7 to 11 are schematic cross-sectional views illustrating a method of manufacturing a display device according to an embodiment.

FIG. 12 is a schematic cross-sectional view of a region corresponding to approximately three pixels of a display device according to still another embodiment.

FIGS. 13 to 15 are schematic cross-sectional views illustrating a method of manufacturing a display device according to an embodiment.

FIG. 16 is a schematic block diagram of an electronic device according to an embodiment.

FIG. 17 is a schematic drawing showing an electronic device according to an embodiment.

### DETAILED DESCRIPTION

Hereinafter, with reference to accompanying drawings, various embodiments of the present disclosure will be described in detail so that a person of an ordinary skill may easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thickness of some layers and regions are exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity (i.e., third direction z).

In addition, unless explicitly described to the contrary, the word “comprise”, and variations such as “comprises” or “comprising”, will be understood to imply the inclusion of stated elements but not the exclusion of any other elements.

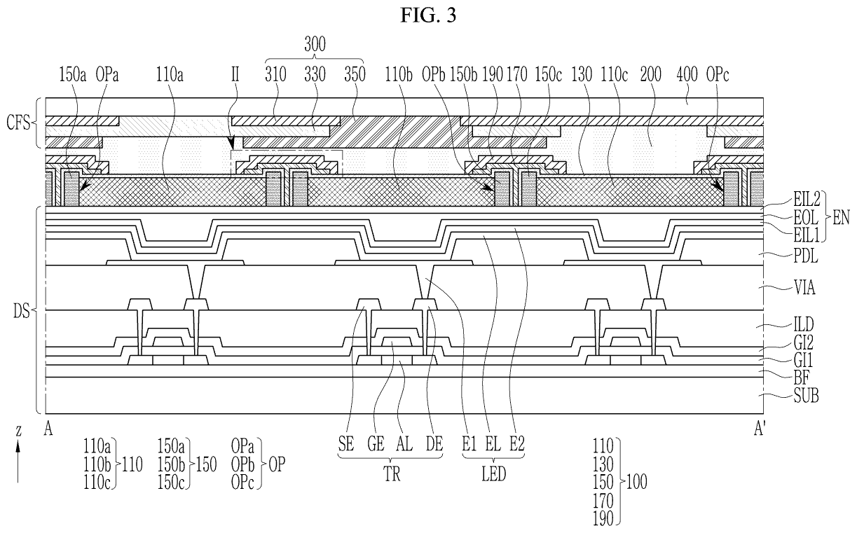

In addition, throughout the specification, when referring to “a plan view”, it means that the target portion is viewed from above (i.e., third direction z: thickness direction of a substrate SUB in FIG. 3), and when referring to “a cross-section view”, it means that a cross section of the target portion cut vertically is viewed from a side.

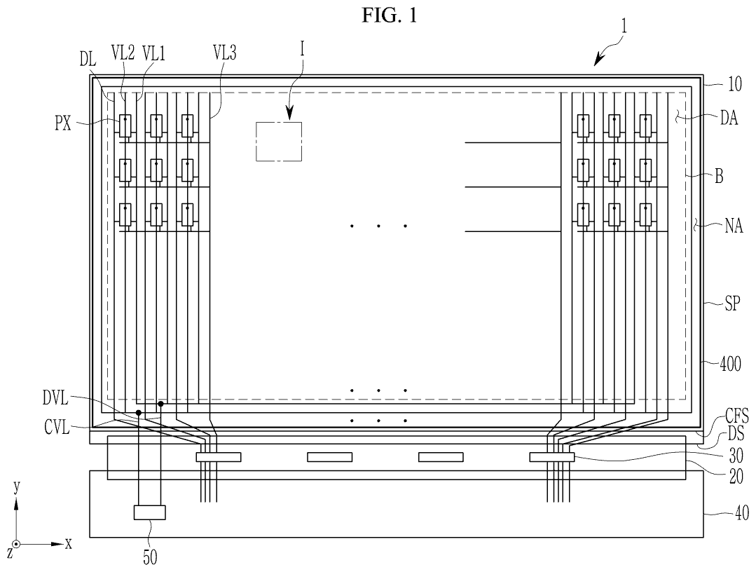

FIG. 1 is a schematic top plan view of a display device according to an embodiment.

Referring to FIG. 1, the display device 1 may be used to display an image in an electronic device. The display device 1 may include a display panel 10, a flexible printed circuit board 20, a driver IC chip 30, a printed circuit board 40, a power module 50, etc.

The display panel 10 may include a display area DA corresponding to a screen for displaying an image and a non-display area NA in which circuits and wires for generating and transmitting various signals applied to the display area DA are arranged. The non-display area NA may be adjacent to the display area DA or may surround the display area DA. In FIG. 1, the inner and outer regions of the boundary line B may be the display area DA and the non-display area NA, respectively.

The display panel 10 may include a display portion DS and a color filter portion CFS. The display portion DS and the color filter portion CFS may be joined by a sealing portion SP disposed around the edge of the display panel 10 between the display portion DS and the color filter portion CFS. The color filter portion CFS may entirely overlap the display portion DS, but the display portion DS may include a region not covered by the color filter portion CFS for connecting or bonding the flexible printed circuit board 20. The display portion DS may include pad portions (not shown) for connecting or bonding the flexible printed circuit board 20. A display portion DS may include a region in which a pad portion is disposed so as to be exposed outside. For example, at a lower portion of display panel 10, the color filter portion CFS may be formed shorter than the display portion DS, and a region where the color filter portion CFS and the display portion DS do not overlap may be provided as a region where the pad portion is disposed. Each of the display portion DS and color filter portion CFS may include regions corresponding to the display area DA and non-display area NA of display panel 10.

The display area DA of the display panel 10 may include pixels (PX). The pixels (PX) may be roughly arranged in a matrix. In addition, a data line DL transmitting data voltages, a driving voltage line VL1 transmitting a driving voltage, a common voltage line VL2 transmitting a common voltage, and an initialization voltage line VL3 transmitting an initialization voltage may be disposed in the display area DA. The driving voltage line VL1, the common voltage line VL2, and the initialization voltage line VL3 may be extended in a second direction y. At least one of the driving voltage line VL1, the common voltage line VL2, and the initialization voltage line VL3 may be connected to an auxiliary voltage line extending in a first direction x.

In the non-display area NA of the display panel 10, a driving voltage transmission line DVL connected to the driving voltage lines VL1, a common voltage transmission line CVL, and the like may be positioned. Each of the driving voltage transmission line DVL and the common voltage transmission line CVL may include portions extending approximately in the second direction y and portions extending approximately in the first direction x. The common voltage transmission line CVL may be disposed to surround the display area DA.

The flexible printed circuit board 20 may have one end connected or boned to the display portion DS of the display panel 10, and the other end connected or bonded to the printed circuit board 40. On the flexible printed circuit board 20, a driver IC chip 30 including a data driver may be disposed.

A power module 50 generating power voltages such as driving voltage and common voltage may be disposed on the printed circuit board 40. The power module 50 may be provided in a form of an IC chip. A signal controller (not shown) controlling a data driver and a gate driver may be disposed on the printed circuit board 40.

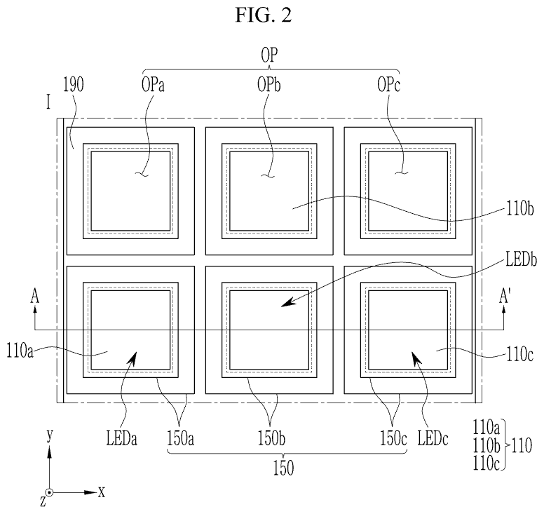

FIG. 2 is a schematic top plan view of a region corresponding to approximately six pixels of a display device according to an embodiment. FIG. 2 may be an enlarged view of region “I” of FIG. 1.

Referring to FIG. 2, the display device may include a color converting layer 110, a bank 150, a metal layer 170, and an anti-reflection layer 190.

The bank 150 may include a first sub-bank 150a, a second sub-bank 150b and a third sub-bank 150c. The bank 150 may define therein openings OP including a first opening OPa, a second opening OPb, and a third opening OPc. The first sub-bank 150a may define the first opening OPa. The second sub-bank 150b may define the second opening OPb. The third sub-bank 150c may define the third opening OPc.

The color converting layer 110 may be disposed in the opening OP of bank 150. A first color converting layer 110a may be disposed in the first opening OPa defined by the first sub-bank 150a. A second color converting layer 110b may be disposed in the second opening OPb defined by the second sub-bank 150b. A third color converting layer 110c may be disposed in the third opening OPc defined by the third sub-bank 150c.

The first opening OPa, the second opening OPb, and the third opening OPc may correspond to the first light emitting element LEDa, the second light emitting element LEDb, and the third light emitting element LEDc, respectively.

FIG. 3 is a schematic cross-sectional view of a region corresponding to approximately three pixels of a display device according to an embodiment. FIG. 3 may correspond to a cross-section of the display device cut along line A-A′ of FIG. 2.

Referring to FIG. 2 and FIG. 3 together, in a display device according to an embodiment, a buffer layer BF may be disposed on a substrate SUB. The buffer layer BF may improve the characteristics of the semiconductor layer AL by blocking impurities from the substrate SUB during the formation of the semiconductor layer AL and may relieve the stress of the semiconductor layer AL by planarizing the surface of the substrate SUB. The buffer layer BF may be an inorganic insulating layer that may include an inorganic insulating material such as silicon nitride (SiNₓ), silicon oxide (SiOₓ), or silicon nitride oxide (SiOₓN_{y}), and may have a single-layer structure or a multi-layer structure.

A plurality of transistors TR may be disposed on the substrate SUB. For example, transistors TR may be disposed on the buffer layer BF disposed on the substrate SUB. The semiconductor layer AL of the transistor TR may be disposed on the substrate SUB. The semiconductor layer AL may include a first semiconductor region, a second semiconductor region, and a channel region disposed between the first semiconductor region and the second semiconductor region. The semiconductor layer AL may include at least one of amorphous silicon, polycrystalline silicon, and oxide semiconductor. For example, the semiconductor layer AL may include low-temperature polycrystalline silicon (LTPS) or oxide semiconductor material including zinc (Zn), indium (In), gallium (Ga), tin (Sn), etc. For example, the semiconductor layer AL may include indium gallium zinc oxide (IGZO).

A first gate insulation layer GI1 may be disposed on the semiconductor layer AL. The first gate insulation layer GI1 may include inorganic insulating materials such as silicon nitride (SiNₓ), silicon oxide (SiOₓ), or silicon nitride oxide (SiOₓNy). The first gate insulation layer GI1 may be a single-layer structure or a multi-layer structure.

A gate conductive layer, which may include a gate electrode GE of a transistor TR, may be disposed on the first gate insulation layer GI1. The gate conductive layer may include molybdenum (Mo), aluminum (Al), copper (Cu), titanium (Ti), etc., and may be a single-layer structure or a multi-layer structure.

A second gate insulation layer GI2 may be disposed on the gate conductive layer. The second gate insulation layer GI2 may include inorganic insulating materials such as silicon nitride (SiNₓ), silicon oxide (SiOₓ), or silicon nitride oxide (SiOₓN_{y}), etc. The second gate insulation layer GI2 may be a single-layer structure or a multi-layer structure.

An interlayer insulation layer ILD may be disposed on the second gate insulation layer GI2. The interlayer insulation layer ILD may include inorganic insulating materials such as silicon nitride (SiNₓ), silicon oxide (SiOₓ), or silicon nitride oxide (SiOₓN_{y}). The interlayer insulation layer ILD may be a single-layer structure or a multi-layer structure. An additional gate conductive layer may be disposed between the second gate insulation layer GI2 and the interlayer insulation layer ILD.

A data conductive layer, which may include a first electrode SE and a second electrode DE of a transistor TR, may be disposed on the interlayer insulation layer ILD. The first electrode SE and the second electrode DE may be connected to the first semiconductor region and the second semiconductor region of the semiconductor layer AL, respectively, through contact holes formed in the insulation layers GI1, GI2, ILD. One of the first electrode SE and the second electrode DE may be a source electrode and the other may be a drain electrode.

The data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), tantalum (Ta), etc. The data conductive layer may be a single-layer structure or a multi-layer structure. For example, the data conductive layer may include a lower layer including a refractory metal such as titanium (Ti), molybdenum (Mo), chromium (Cr), or tantalum (Ta), a middle layer including a metal with low resistivity such as aluminum (Al), copper (Cu), or silver (Ag), and an upper layer including a refractory metal. For example, the data conductive layer may have a triple layer structure such as titanium (Ti)/aluminum (Al)/titanium (Ti).

A first insulation layer VIA may be disposed on the data conductive layer. The first insulation layer VIA disposed on the data conductive layer may be provided as a planarization layer. For example, a first insulation layer VIA, which may be provided as a planarization layer, may be disposed on the plurality of transistors TR including a semiconductor layer AL, a gate electrode GE, a first electrode SE, and a second electrode DE.

The first insulation layer VIA may include organic insulating materials such as common polymers such as polymethylmethacrylate, polystyrene, polymer derivatives having phenolic groups, acryl-based polymers, imide polymers (e.g., polyimide), and siloxane polymers.

The light emitting elements LED may be disposed on the first insulation layer VIA. Each light emitting element LED may be electrically connected to a transistor TR. The light emitting elements LED may include a first light emitting element, a second light emitting element, and a third light emitting element that are adjacent to each other. For example, the first light emitting element may refer to a light emitting element LED in a region overlapping the first color converting layer 110a. The second light emitting element may refer to a light emitting element LED in a region overlapping the second color converting layer 110b. The third light emitting element may refer to a light emitting element LED in a region overlapping the third color converting layer 110c.

A light emitting element LED may include a first electrode E1, a light emitting layer EL and a second electrode L2. The first electrode E1 may be disposed on the first insulation layer VIA and connected to the transistor TR. The first electrode E1 may be referred to as a pixel electrode and may serve as an anode of the light emitting element. The first electrode E1 may be connected to one of a first electrode SE and a second electrode DE of the transistor TR through a contact hole formed in the first insulation layer VIA. The first electrode E1 may include a reflective conductive material or a semi-transparent conductive material, or may include a transparent conductive material. The first electrode E1 may contain a metal or metal alloy such as lithium (Li), calcium (Ca), aluminum (Al), silver (Ag), magnesium (Mg), or gold (Au). The first electrode E1 may be a single-layer structure or a multi-layer structure. For example, it may have a triple-layer structure such as ITO (indium tin oxide)/Ag (silver)/ITO.

A second insulation layer PDL defines therein a plurality of pixel openings overlapping the first electrode E1 may be disposed on the first insulation layer VIA. The second insulation layer PDL may be provided as a pixel defining layer. The pixel opening of the second insulation layer PDL may overlap a part of the first electrode E1.

The second insulation layer PDL may include organic insulating materials such as common polymers such as polymethylmethacrylate and polystyrene, polymer derivatives having phenolic groups, acryl-based polymers, imide polymers, and siloxane polymers.

A light emitting layer EL may be disposed on a plurality of first electrodes E1. The light emitting layer EL is a layer in which electricity-to-light conversion occurs through combination of electrons and holes, and may include at least one of an organic material and an inorganic material that emits light of a specific color. The light emitting layer EL may overlap the first electrode E1 and may be disposed on the entire display area DA described with reference to FIG. 1.

A functional layer may be disposed between the first electrode E1 and the light emitting layer EL, and on the light emitting layer EL. The functional layer may include at least one of a hole injection layer HIL, a hole transport layer HTL, an electron transport layer ETL, and an electron injection layer EIL. The functional layer may include a first functional layer disposed between the first electrode E1 and the light emitting layer EL, and a second functional layer disposed between the light emitting layer EL and the second electrode E2. The first functional layer may include at least one of the hole injection layer HIL and the hole transport layer HTL. The second functional layer may include at least one of the electron transport layer ETL and the electron injection layer EIL. At least part of the functional layer may be disposed in the pixel opening of the second insulation layer PDL. The functional layer may be disposed across the entire display area DA described with reference to FIG. 1.

The second electrode E2 may be disposed on the light emitting layer EL. The second electrode E2 may transmit common voltage and may be referred to as the common electrode. The second electrode E2 may be provided as a cathode of the light emitting element LED. The second electrode E2 may contain a metal or metal alloy such as lithium (Li), calcium (Ca), aluminum (Al), silver (Ag), magnesium (Mg), or gold (Au). The second electrode E2 may be a single-layer structure or a multi-layer structure. For example, the second electrode E2 may have a triple-layer structure such as ITO/Ag/ITO.

A pixel capping layer (not shown) may be disposed on the second electrode E2. The pixel capping layer may improve light efficiency by adjusting the refractive index.

An encapsulation layer EN may be disposed on the light emitting element LED including the first light emitting element, the second light emitting element, and the third light emitting element. The encapsulating layer EN may encapsulate the light emitting element LED including a light emitting layer EL to prevent moisture or oxygen from penetrating from the outside. The encapsulation layer EN may be a thin film encapsulation layer comprising one or more inorganic layers EIL1 and EIL2 and one or more organic layers EOL. For example, the encapsulation layer EN may be a thin film encapsulation layer having a triple-layer structure such as first inorganic layer EIL1/organic layer EOL/second inorganic layer EIL2.

The color converting portion 100 may be disposed on the encapsulation layer EN. The color converting portion 100 may include a color converting layer 110, a capping layer 130, a bank 150, a metal layer 170, and an anti-reflection layer 190. A bank 150 of the color converting portion 100 may be disposed on the encapsulation layer EN. The bank 150 may define therein a first opening OPa, a second opening OPb, and a third opening (OPc), and the first opening OPa, the second opening OPb, and the third opening OPc may overlap the first light emitting element, the second light emitting element, and the third light emitting element, respectively. The bank 150 may include a first sub-bank 150a, a second sub-bank 150b and a third sub-bank 150c. The first sub-bank 150a may define the first opening OPa overlapping the first light emitting element. The second sub-bank 150b may define a second opening OPb overlapping the second light emitting element. The third sub-bank 150c may define a third opening OPc overlapping the third light emitting element.

The first sub-bank 150a, second sub-bank 150b and third sub-bank 150c may be spaced apart from one another. For example, the first sub-bank 150a and the second sub-bank 150b may be disposed apart from each other by a predetermined interval. The first sub-bank 150a and the third sub-bank 150c may be disposed apart from each other at a predetermined interval. The second sub-bank 150b and third sub-bank 150c may be disposed apart from each other at a predetermined interval. At least one of the first sub-bank 150a and the second sub-bank 150b, the first sub-bank 150a and the third sub-bank 150c, and the second sub-bank 150b and the third sub-bank 150c may be interconnected.

The bank 150 may be hydrophobic. For example, surface energy of the bank 150 may be equal to or less than about 25 dyne/cm. In the inkjet process for forming the color converting layer 110, the spreading of droplets incorrectly landed on the bank 150 or at an edge of the bank 150 may be controlled, which may reduce the stay of droplets on the bank 150 or at an edge of the bank 150 and reduce the size of the incorrectly landed droplets. Hydrophobicity of the bank 150 may be given by forming the bank 150 using a photosensitivity resin composition containing a hydrophobic material, or hydrophobic treating the surface of the bank 150 through, for example, plasma treatment, after forming the bank 150. The bank 150 may include organic materials such as acryl-based polymer, epoxy polymer, imide polymer, olefin polymer, amide polymer, etc.

The bank 150 may be transparent. “transparent” may mean that visible light transmittance is about 50% or greater, about 60% or greater, or about 70% or greater. If the bank 150 contains black pigment, since light emitted laterally from the color converting layer 110 is absorbed by the bank 150, recycling the laterally emitted light may be difficult. In addition, if the bank 150 contains black pigment, since the bank 150 absorbs light, which makes it difficult to expose (e.g., irradiate with ultraviolet rays) a lower portion during the process of forming the bank 150, and thus, the critical dimension may increase. Even if the bank 150 contains white pigment, it may be difficult to control the fine structure due to diffuse reflection. By forming the bank 150 with transparent material, the lateral emitted light may be recycled and high resolution may be easily implemented. Also, the cost of forming the bank 150 may be reduced.

The color converting layer 110 of the color converting portion 100 may be disposed on the encapsulation layer EN. The color converting layer 110 may include a first color converting layer 110a, a second color converting layer 110b, and a third color converting layer 110c. The first color converting layer 110a may be disposed in the first opening OPa. The second color converting layer 110b may be disposed in the second opening OPb. The third color converting layer 110c may be disposed in the third opening OPc. The first color converting layer 110a, the second color converting layer 110b and the third color converting layer 110c may be partitioned or separated by the bank 150 including the first sub-bank 150a, the second sub-bank 150b and the third sub-bank 150c.

The first sub-bank 150a is separated from the second sub-bank 150b and the third sub-bank 150c and may surround the first color converting layer 110a. The second sub-bank 150b is separated from the first sub-bank 150a and the third sub-bank 150c and may surround the second color converting layer 110b. The third sub-bank 150c is separated from the first sub-bank 150a and the second sub-bank 150b and may surround the third color converting layer 110c.

The first color converting layer 110a may overlap the light emitting region of the light emitting element LED. For example, the first color converting layer 110a may overlap the light emitting region of the first light emitting element. The first color converting layer 110a may convert light incident from the light emitting layer EL of the first light emitting element into light of the first wavelength. The light of the first wavelength may be red light with a maximum light emitting peak wavelength of about 600 nanometers (nm) to about 650 nm. For example, the first color converting layer 110a may convert light incident from the first light emitting element into red light.

The second color converting layer 110b may overlap the light emitting region of the light emitting element LED. For example, the second color converting layer 110b may overlap the light emitting region of the second light emitting element. The second color converting layer 110b may convert light incident from the light emitting layer EL of the second light emitting element into light of the second wavelength. The light of the second wavelength may be green light with a maximum light emitting peak wavelength of about 500 nm to about 550 nm. For example, the second color converting layer 110b may convert light incident from the second light emitting element into green light.

The third color converting layer 110c may overlap the light emitting region of the third emitting element LED. For example, the third color converting layer 110c may overlap the light emitting region of the third light emitting element. The third color converting layer 110c may convert light incident from the light emitting layer EL of the third light emitting element into light of the third wavelength. The light of the third wavelength may be blue light with a maximum light emitting peak wavelength of about 380 nm to about 480 nm. For example, the third color converting layer 110c may convert light incident from the third light emitting element into blue light. The third color converting layer 110c may also be referred to as a light transmitting layer. For example, the light emitting element LED including the third light emitting element may emit blue light having a maximum light emitting peak wavelength of about 380 nm to about 480 nm. The third color converting layer 110c may transmit blue light incident from the third light emitting element.

The first color converting layer 110a, the second color converting layer 110b, and the third color converting layer 110c may include first quantum dots, second quantum dots, and third quantum dots, respectively. Light incident on the first color converting layer 110a may be converted into light of the first wavelength by the first quantum dots and then emitted. Light incident on the second color converting layer 110b may be converted into light of the second wavelength by the second quantum dots and then emitted. Light incident on the third color converting layer 110c may be converted into light of a third wavelength by the third quantum dots and then emitted.

When the light emitted from the light emitting element LED is blue light, the first color converting layer 110a and the second color converting layer 110b may each include first quantum dots and second quantum dots. Wavelength of light incident on the third color converting layer 110c may not be converted.

The first color converting layer 110a, the second color converting layer 110b, and the third color converting layer 110c may include scatterers. The scatterers may improve light efficiency by scattering light incident on the first color converting layer 110a, the second color converting layer 110b, and the third color converting layer 110c.

Each of the first quantum dot, the second quantum dot, and the third quantum dot (hereinafter, quantum dot also referred to as semiconductor nanocrystal) may independently include a group II-VI compound, a group III-V compound, a group IV-VI compound, a group IV element or compound, a group I-III-VI compound, a group II-III-VI compound, a group I-II-IV-VI compound, or a combination thereof.

Group II-VI compound may selected from a group consisting of: a binary compound selected from the group consisting of CdSe, CdTe, ZnS, ZnSe, ZnTe, ZnO, HgS, HgSe, HgTe, MgSe, MgS and a mixture thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and a tetratomic compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof. Group II-VI compounds may additionally contain group III metals.

III-V group compound may be selected a group consisting of: a binary compound selected from the group consisting of GaN, GaP, GaAs, GaSb, AlN, AlP, AlAs, AlSb, InN, InP, InAs, InSb and a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb and a mixture thereof; and a tetratomic compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. Group III-V compounds may also contain additional group II metals (e.g., InZnP).

The group IV-VI compound may be selected from a group consisting of: a binary compound selected from the group consisting of SnS, SnSe, SnTe, PbS, PbSe, PbTe and a mixture thereof; a ternary compound selected from the group consisting of SnSeS, SnSeTe, SnSTe, PbSeS, PbSeTe, PbSTe, SnPbS, SnPbSe, SnPbTe and a mixture thereof; and a tetratomic compound selected from the group consisting of SnPbSSe, SnPbSeTe, SnPbSTe and a mixture thereof.

The group IV element or compound may be selected from a group consisting of: a simplex compound selected from the group consisting of Si, Ge and a combination thereof; and a binary compound selected from the group consisting of SiC, SiGe and a combination thereof.

Group I-III-VI compounds may be selected from CuInSe2, CuInS2, CuInGaSe and CuInGaS.

The group II-III-VI compound may be selected from a group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe and a combination thereof.

Group I-II-IV-VI compounds may be selected from CuZnSnSe and CuZnSnS.

Quantum dots may not contain cadmium. Quantum dots may include III-V group compound-based semiconductor nanocrystals containing indium and phosphorus. Group III-V compounds may further contain zinc. The quantum dots may include II-VI compound-based semiconductor nanocrystals containing chalcogen elements (e.g., sulfur, selenium, tellurium, or combination thereof) and zinc.

In quantum dots, binary compounds, ternary compounds, and/or tetratomic compounds may exist within a particle with uniform concentration, or may exist within the same particle with split by partially different concentration distributions. Also, quantum dots may have a core-shell structure that one quantum dot surrounds another quantum dot. The interface between the core and the shell may have a concentration gradient that the concentration of an element presented in the shell gradually decreases toward the center.

Quantum dots may have a core-shell structure including a core containing nanocrystals and a shell surrounding the core. The shell of a quantum dot may act as a protective layer to maintain semiconductor characteristics by preventing chemical modification of the core and/or as a charging layer to provide electrophoresis characteristics to the quantum dot. The shell may be a single-layer structure or a multi-layer structure. The interface between the core and the shell may have a concentration gradient that the concentration of an element presented in the shell gradually decreases toward the center. Examples of a shell of quantum dot may be metal oxide or non-metal oxides, semiconductor compounds, or combinations thereof.

The metal oxide or non-metals may be, for example, binary compounds such as SiO2, Al2O3, TiO2, ZnO, MnO, Mn2O3, Mn3O4, CuO, FeO, Fe2O3, Fe3O4, CoO, Co3O4, NiO, or ternary compounds such as MgAl2O4, CoFe2O4, NiFe2O4, CoMn2O4.

The semiconductor compounds may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

Quantum dots may have a full width of half maximum of a light emitting peak wavelength spectrum of about 45 nm or less, about 40 nm or less, or about 30 nm or less, and color purity or color reproducibility may be improved within this range. Additionally, since light emitted through quantum dots is emitted in all directions, the viewing angle may be improved.

In the quantum dot, the shell material and the core material may have different energy bandgaps. For example, the energy bandgap of the shell material may be larger or smaller than the energy bandgap of the core material. The quantum dots may have multi-layered shells. In a multi-layered shell, the energy bandgap of the outer layer may be larger than the energy bandgap of the inner layer closer to the core. In a multi-layered shell, the energy bandgap of the outer layer may be smaller than the energy bandgap of the inner layer.

A shape of a quantum dot is not particularly limited. For example, the shape of a quantum dot may include a sphere, a polyhedron, a pyramid, a multipod, a square, a rectangular parallelepiped, a nanotube, a nanorod, a nanowire, a nanosheet, or a combination thereof.

The quantum dot may include an organic ligand having, for example, a hydrophobic moiety and/or a hydrophilic moiety. The organic ligand moieties may be bound to the surface of quantum dots. The organic ligand may include RCOOH, RNH2, R2NH, R3N, RSH, R3PO, R3P, ROH, RCOOR, RPO(OH)2, RHPOOH, R2POOH, or combination thereof. Here, R may be, respectively and independently, a substituted or unsubstituted alkyl group having a carbon number of C3 to C40 (e.g., C5 or more and C24 or less), a substituted or unsubstituted alkenyl group or other substituted or unsubstituted aliphatic hydrocarbon group having a carbon number of C3 to C40, a substituted or unsubstituted aryl group or other substituted or unsubstituted aromatic hydrocarbon group having a carbon number of C6 to C40 (e.g., C6 or more and C20 or less), or a combination thereof.

Examples of the organic ligand may be: thiol compounds such as methane thiol, ethane thiol, propane thiol, butane thiol, pentane thiol, hexane thiol, octane thiol, dodecane thiol, hexadecane thiol, octadecane thiol, benzyl thiol, etc.; amines such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributyl amine, trioctyl amine, etc.; carboxylic acid compounds such as methane acid, ethanoic acid, propane acid, butanoic acid, pencarbonate, hexanoic acid, hexadecanoic acid, dodecanoic acid, hexadecanoic acid, octadecanoic acid, oleic acid (oleic acid), and benzoic acid; phosphine compounds or its oxide compounds such as methyl phosphine, ethyl phosphine, propyl phosphine, butyl phosphine, pentyl phosphine, octyl phosphine, dioctyl phosphine, tributyl phosphine, trioctyl phosphine, methyl phosphine oxide, ethyl phosphine oxide, propyl phosphine oxide, butyl phosphine oxide, pentyl phosphine oxide, tributyl phosphine oxide, octylphosphine oxide, dioctyl phosphine oxide, and trioctylphosphine oxide;

Di-phenyl phosphine, tri-phenyl phosphine compound or their oxide compound; alkyl phosphinic acid of C5 to C20, alkyl phosphonic acid of C5 to C20, such as hexylphosphinic acid, octylphosphinic acid, dodecanephosphinic acid, tetradecanephosphinic acid, hexadecanephosphinic acid, octadecanephosphinic acid; and the like. The quantum dot may contain hydrophobic organic ligands alone or as a mixture of one or more. The hydrophobic organic ligand, which may contain an acrylate group, a methacrylate group, and the like, may not contain a photopolymerizable moiety.

A capping layer 130 may be disposed on the color converting layer 110 and the bank 150. The capping layer 130 may be disposed between the bank 150 and the metal layer 170. The capping layer 130 may be disposed to cover the entirety of the color converting layer 110 and the bank 150. The capping layer 130 may be disposed to cover all of the first color converting layer 110a, the second color converting layer 110b, and the third color converting layer 110c. Accordingly, the color converting layer 110 may be protected by the capping layer 130. The capping layer 130 may contain an inorganic insulating material such as silicon oxide (SiOₓ), silicon nitride (SiNₓ), or silicon nitride (SiOₓN_{y}), and may have a single-layer structure or a multi-layer structure.

A metal layer 170 may be disposed on the bank 150. The metal layer 170 may cover the entirety of the bank 150 in a plan view, and may also cover an edge portion of the color converting layer 110 together. “edge portion of the color converting layer 110” may mean a region within a certain distance from an edge of color converting layer 110. The anti-reflection layer 190 may cover the metal layer 170 in a plan view. The metal layer 170 may cover the bank 150. The metal layer 170 may cover all of the first sub-bank 150a, the second sub-bank 150b, and the third sub-bank 150c. The metal layer 170 may be disposed between the first sub-bank 150a and the second sub-bank 150b. The metal layer 170 may be disposed between second sub-bank 150b and third sub-bank 150c. The metal layer 170 may be disposed between second sub-bank 150b and third sub-bank 150c.

The metal layer 170 may fill at least a portion of a space between the first sub-bank 150a and the second sub-bank 150b. For example, the first sub-bank 150a and the second sub-bank 150b may be separated between the first color converting layer 110a and the second color converting layer 110b. At least a portion of the space between the first sub-bank 150a and the second sub-bank 150b, which are separated from each other, may be filled with the metal layer 170. For example, the capping layer 130 may be disposed on the first sub-bank 150a and the second sub-bank 150b. Among the space between the first sub-bank 150a and the second sub-bank 150b, a space between the capping layer 130 disposed on the first sub-bank 150a and the second sub-bank 150b may be filled with the metal layer 170. Accordingly, it is possible to prevent the light passing through the first color converting layer 110a and the light passing through the second color converting layer 110b from being mixed.

The metal layer 170 may fill at least a portion of a space between the first sub-bank 150a and the third sub-bank 150c. For example, the first sub-bank 150a and the third sub-bank 150c may be separated between the first color converting layer 110a and the third color converting layer 110c. At least a portion of the space between the first sub-bank 150a and the third sub-bank 150c, which are separated from each other, may be filled with the metal layer 170. For example, the capping layer 130 may be disposed on the first sub-bank 150a and the third sub-bank 150c. Among the space between the first sub-bank 150a and the third sub-bank 150c, a space between the capping layer 130 disposed on the first sub-bank 150a and the third sub-bank 150c may be filled with the metal layer 170. Accordingly, it is possible to prevent the light passing through the first color converting layer 110a and the light passing through the third color converting layer 110c from being mixed.

The metal layer 170 may fill at least a portion of a space between the second sub-bank 150b and the third sub-bank 150c. The second sub-bank 150b and the third sub-bank 150c may be separated between the second color converting layer 110b and the third color converting layer 110c. At least a portion of the space between the second sub-bank 150b and the third sub-bank 150c, which are separated from each other, may be filled with the metal layer 170. For example, the capping layer 130 may be disposed on the second sub-bank 150b and the third sub-bank 150c. Among the space between the second sub-bank 150b and the third sub-bank 150c, a space between the capping layer 130 disposed on the second sub-bank 150b and the third sub-bank 150c may be filled with the metal layer 170. Accordingly, it is possible to prevent the light passing through the second color converting layer 110b and the light passing through the third color converting layer 110c from being mixed.

An anti-reflection layer 190 may be disposed on the metal layer 170. The anti-reflection layer 190 may contain substantially the same material as the color filter layer 300. Accordingly, it may be prevented that light is reflected by the metal layer 170 disposed between neighboring banks 150 and then light of an arbitrary color is emitted from the interval between the pixels.

The anti-reflection layer 190 may cover the entirety of the metal layer 170. The anti-reflection layer 190 may partially cover the color converting layer 110. The anti-reflection layer 190 may cover a part of the first color converting layer 110a, a part of the second color converting layer 110b, and a part of the third color converting layer 110c. For example, the anti-reflection layer 190 may cover an edge portion of the first color converting layer 110a, an edge portion of the second color converting layer 110b, and an edge portion of the third color converting layer 110c. “Edge portion of the first color converting layer 110a” may mean a region within a certain distance from an edge of the first color converting layer 110a. “Edge portion of the second color converting layer 110b” may mean a region within a certain distance from an edge of the second color converting layer 110b. “Edge portion of the third color converting layer 110c” may mean a region within a certain distance from an edge of the third color converting layer 110c.

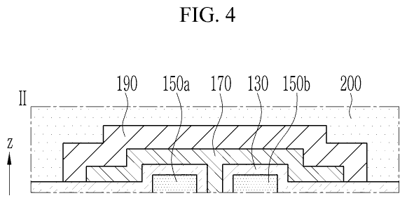

FIG. 4 is a schematic cross-sectional view of a part of a color converting layer included in a display device according to an embodiment. FIG. 4 may be an enlarged view of region “II” of FIG. 3.

Referring to FIGS. 2 to 4, the anti-reflection layer 190 may cover both an upper surface and a side surface of the metal layer 170. Accordingly, the anti-reflection layer 190 may prevent light from being reflected from a front surface of the metal layer 170.

A third insulation layer 200 may be disposed on the color converting layer 110 and the anti-reflection layer 190. The third insulation layer 200 may be provided as a bonding member bonding the color converting portion 100 and the color filter layer 300. The third insulation layer 200 may be used as the sealing portion described with reference to FIG. 1. The third insulation layer 200 may completely cover the color converting portion 100. The third insulation layer 200 may contain an organic insulating material such as an acryl-based polymer.

A color filter layer 300 may be disposed on the third insulation layer 200. The color filter layer 300 may include a first color filter layer 310, a second color filter layer 330, and a third color filter layer 350, which transmit light of different wavelengths from each other. The first color filter layer 310, the second color filter layer 330, and the third color filter layer 350 may correspond to the first color converting layer 110a, the second color converting layer 110b, and the third color converting layer 110c of the color converting portion 100, respectively. The first color filter layer 310, the second color filter layer 330, and the third color filter layer 350 may overlap the first opening OPa, the second opening OPb, and the third opening OPc of the color converting portion 100, respectively.

The first color filter layer 310, the second color filter layer 330, and the third color filter layer 350 may transmit light of wavelengths different each other, and absorb light of the remaining wavelengths, respectively. For example, the first color filter layer 310 may transmit light of a first wavelength and absorb light of other wavelengths. The second color filter layer 330 may transmit light of a second wavelength and absorb light of other wavelengths. The third color filter layer 350 may transmit light of a third wavelength and absorb light of other wavelengths. Accordingly, the purity of light emitted from the display area (e.g., light of the first wavelength, light of the second wavelength, and light of the third wavelength) may be increased. The light of the first wavelength, the light of the second wavelength, and the light of the third wavelength may be red light, green light, and blue light, respectively.

The color filter layers 300 that absorb light of different wavelengths may overlap each other to form a light-shielding region. At least two of the first color filter layer 310, the second color filter layer 330, and the third color filter layer 350 may overlap each other to form a light-shielding region. For example, the light-shielding region may be formed by overlapping all of the first color filter layer 310, the second color filter layer 330, and the third color filter layer 350, or the light-shielding region also may be formed by overlapping two of the first color filter layer 310, the second color filter layer 330, and the third color filter layer 350. In FIG. 3, the first color filter layer 310, the second color filter layer 330, and the third color filter layer 350 are shown to be sequentially laminated, but they may be laminated in a different order.

The upper substrate 400 may be disposed on the color filter layer 300. The upper substrate 400 may contain substantially the same material as the substrate SUB. The upper substrate 400 may contain a material having a rigid characteristic, such as glass, or a material having a flexible characteristic, such as plastic. For example, the upper substrate 400 may be a glass substrate and may also contain a polymer material such as polyimide, polyamide, polyethylene terephthalate, etc. The aforementioned color filter portion CFS may include the color filter layer 300 and the upper substrate 400.

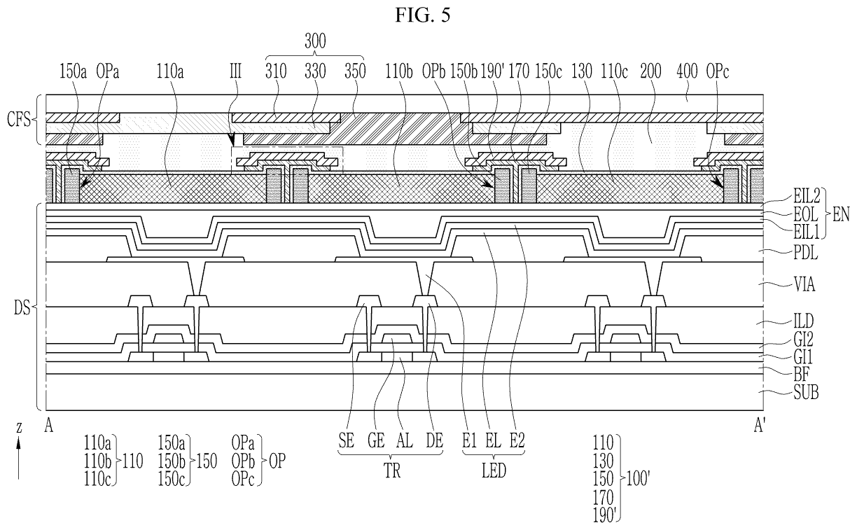

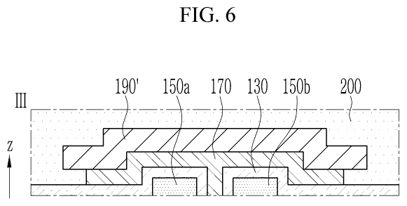

FIG. 5 is a schematic cross-sectional view of a region corresponding to approximately three pixels of a display device according to another embodiment. FIG. 5 is a schematic cross-sectional view showing a cross-section of the display device taken along line A-A′ of FIG. 2. FIG. 6 is a schematic cross-sectional view of a part of a color converting layer included in a display device according to an embodiment. FIG. 6 is an enlarged view of a region “III” of FIG. 5. In explaining FIG. 5 and FIG. 6, explanations of substantially the same as or similar to those explained with reference to FIGS. 1 to 4 will be omitted.

Referring to FIG. 5 and FIG. 6, the color converting portion 100′ may include a color converting layer 110, a capping layer 130, a bank 150, a metal layer 170 and an anti-reflection layer 190′. An anti-reflection layer 190′ may be disposed on the metal layer 170. The anti-reflection layer 190′ may cover an upper surface of the metal layer 170. The anti-reflection layer 190′ may not cover at least a portion of a side surface of the metal layer 170. The anti-reflection layer 190′ may cover the entirety of the upper surface of the metal layer 170, and may not cover at least a portion of the side surface of the metal layer 170. For example, the anti-reflection layer 190′ may not cover the outermost side surface of the side surfaces of the metal layer 170. “Outermost side surface of the side surfaces of the metal layer 170” may mean a side surface of an edge among the side surfaces of the metal layer 170. Accordingly, the metal layer 170 and the anti-reflection layer 190′ may be formed with the same mask. Therefore, process costs may be reduced, and process efficiency may be improved.

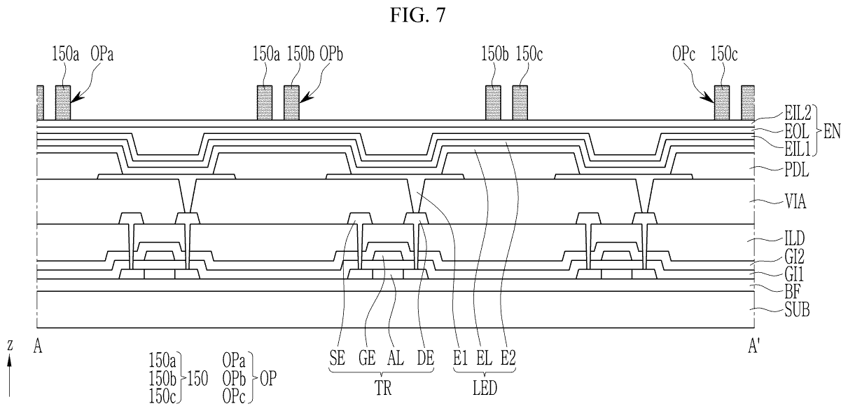

FIGS. 7 to 10 are schematic cross-sectional views illustrating a method of manufacturing a display device according to an embodiment. FIGS. 7 to 10 are schematic cross-sectional views illustrating a method of manufacturing the color converting portion according to display device of FIG. 3.

Referring to FIG. 7, a buffer layer BF may be formed on the substrate SUB, and a transistor TR may be formed on the buffer layer BF. For example, after forming buffer layer BF is formed on a substrate SUB and forming a semiconductor material layer on the buffer layer BF, a semiconductor layer AL may be formed by patterning. A first gate insulation layer GI1 may be formed on the semiconductor layer AL. By forming a conductive material layer on the first gate insulation layer GI1 and then patterning it, a gate conductive layer including the gate electrode GE of the transistor TR may be formed by patterning the conductive material layer. A second gate insulation layer GI2 may be formed on the gate conductive layer. An interlayer insulation layer ILD may be formed on the second gate insulation layer GI2. By forming a conductive material layer on an interlayer insulation layer ILD and the patterning it, a data conductive layer including a first electrode SE and second electrode DE of a transistor TR may be formed. Contact holes overlapping the first electrode SE and second electrode DE of the transistor TR may be formed in the first gate insulation layer GI1, the second gate insulation layer GI2, and the interlayer insulation layer ILD. The first electrode SE and second electrode DE of the transistor TR may be connected to the semiconductor layer AL through the contact holes formed in the first gate insulation layer GI1, the second gate insulation layer GI2, and the interlayer insulation layer ILD.

A first insulation layer VIA may be formed on the first electrode SE and second electrode DE of the transistor TR. The first insulation layer VIA may be referred to as a planarization layer. A contact hole overlapping at least one of the first electrode SE and second electrode DE of the transistor TR may be formed in the first insulation layer VIA. A light emitting element LED electrically connected to a transistor TR may be formed on the first insulation layer VIA.

By forming a conductive material layer on the first insulation layer VIA and then patterning it, the first electrode E1 of the light emitting element LED may be formed. The first electrode E1 may be connected to the transistor TR through the contact hole formed in the first insulation layer VIA. A second insulation layer PDL may be formed on the first electrode E1 of a light emitting element LED. The second insulation layer PDL may be referred to as a pixel defining layer.

A light emitting layer EL may be formed on the first electrode E1 of a light emitting element LED and second insulation layer PDL. The first electrode E1 of the light emitting element LED may be formed in plural spaced apart from each other. The light emitting element LED may include a plurality of light emitting elements LED spaced apart from each other by a plurality of first electrodes E1. For example, a light emitting element LED may be formed to include first light emitting element LEDa, second light emitting element LEDb, and third light emitting element LEDc neighboring one another as described with reference to FIG. 2.

Between the first electrode E1 and the light emitting layer EL of the light emitting element LED, and on the light emitting layer EL, a functional layer that may include a hole injection layer HIL, a hole transport layer HTL, an electron transport layer ETL, and an electron injection layer EIL may be formed. For example, a first functional layer, which may include a hole injection layer HIL and a hole transport layer HTL, may be formed between the first electrode E1 and the light emitting layer EL. A second functional layer, which may include an electron transport layer ETL and an electron injection layer EIL, may be formed on the light emitting layer EL. For example, a first functional layer, a light emitting layer EL, and a second functional layer may be formed sequentially. The first functional layer, the light emitting layer EL, and the second functional layer may be deposited over the entire surface using an open mask. Accordingly, the first function layer, the light emitting layer EL, and the second function layer may be formed over the entire display area.

The second electrode E2 of the light emitting element LED may be formed on the light emitting layer EL. An encapsulating layer EN may be formed on the second electrode E2. The encapsulation layer EN may be formed to include one or more inorganic layers EIL1 and EIL2 and one or more organic layers EOL. A capping layer may be further formed between the second electrode of the light emitting element LED and the encapsulation layer EN, or on the encapsulation layer EN.

A bank 150 defining therein an opening OP overlapping the light emitting element LED may be formed on the encapsulation layer EN. The bank 150 may be formed through a first mask. The bank 150 may be formed by applying a liquid-repellent material, organic material, and the like, and patterning it using the first mask. For example, a first sub-bank 150a defining therein a first opening OPa overlapping the first light emitting element, a second sub-bank 150b defining therein a second opening OPb overlapping the second light emitting element, and a third sub-bank 150c defining therein a third opening OPc overlapping the third light emitting element may be formed on the encapsulation layer EN. The first sub-bank 150a, second sub-bank 150b and third sub-bank 150c may be formed to be spaced apart from one another. All of the first sub-bank 150a, the second sub-bank 150b, and the third sub-bank 150c may be formed using the first mask.

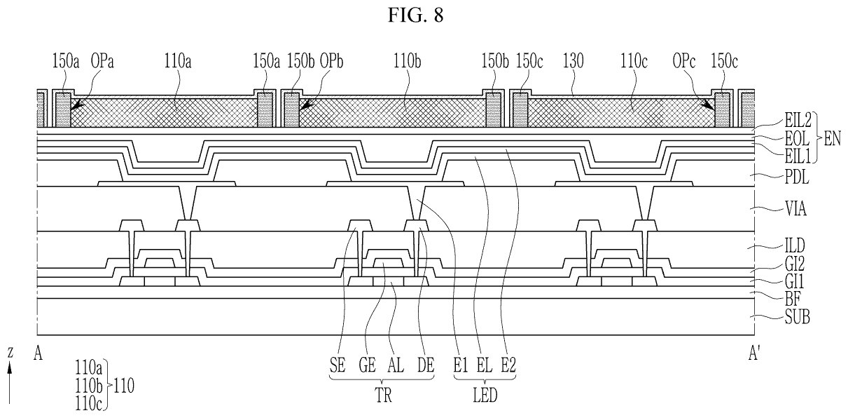

Referring to FIG. 8, a color converting layer 110 may be formed in the opening OP of the bank 150. A first color converting layer 110a may be formed in the first opening OPa of the first sub-bank 150a. A second color converting layer 110b may be formed in the second opening OPb of the second sub-bank 150b. A third color converting layer 110c may be formed in the third opening OPc of the third sub-bank 150c. The color converting layer 110 including the first color converting layer 110a, the second color converting layer 110b, and the third color converting layer 110c may be formed through an inkjet process. A capping layer 130 may be formed on the color converting layer 110 and the bank 150. The capping layer 130 may be formed to cover all of the color converting layer 110 including the first color converting layer 110a, the second color converting layer 110b, and the third color converting layer 110c, and the bank 150 including the first sub-bank 150a, the second sub-bank 150b, and the third sub-bank 150c.

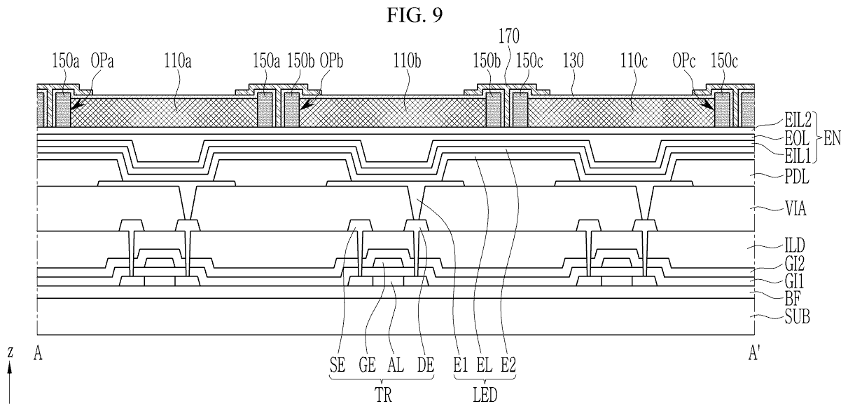

Referring to FIG. 9, a metal layer 170 may be formed on the bank 150. The metal layer 170 may be formed between the first sub-bank 150a and the second sub-bank 150b, between the first sub-bank 150a and the third sub-bank 150c, and between the second sub-bank 150b and the third sub-bank 150c. For example, the metal layer 170 may be formed on upper surfaces and side surfaces of the first sub-bank 150a, the second sub-bank 150b, and the third sub-bank 150c. A capping layer 130 may be formed between the bank 150 and the metal layer 170. The metal layer 170 may be formed through a second mask. The metal layer 170 may be formed by applying metal on the bank 150 or the capping layer 130 and then patterning it using the second mask. The metal layer 170 may be formed to fill at least a portion of spaces between the first sub-bank 150a and the second sub-bank 150b, between the first sub-bank 150a and the third sub-bank 150c, and between the second sub-bank 150b and the third sub-bank 150c.

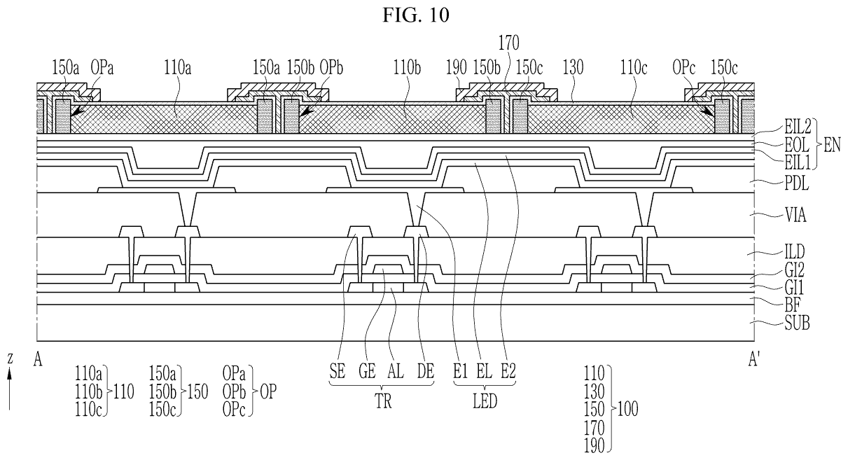

Referring to FIG. 10, an anti-reflection layer 190 may be formed on the metal layer 170. An anti-reflection layer 190 may be formed on the metal layer 170 to form a color converting portion 100 including a color converting layer 110, a capping layer 130, a bank 150, a metal layer 170, and an anti-reflection layer 190. The anti-reflection layer 190 may be formed using a third mask. The anti-reflection layer 190 may be formed by applying a material contained in the color filter layer on at least one of the color converting layer 110, the capping layer 130, and the metal layer 170, and patterning it using the third mask. The material applied to form the anti-reflection layer 190 may be substantially the same material as the color filter layer 300 described with reference to FIGS. 3 to 6. The third mask may be a mask different from the second mask. The anti-reflection layer 190 may be formed to cover the entirety of the metal layer 170. The anti-reflection layer 190 may be formed to partially cover the color converting layer 110. Accordingly, light may be prevented from being reflected from a front surface of the metal layer 170.

The first mask, the second mask, and the third mask may be masks different from each other. Accordingly, the entirety of the bank 150 may be covered by the metal layer 170, and the entirety of the metal layer 170 may be covered by the anti-reflection layer 190. Accordingly, even reducing the number of masks used in forming the color converting portion 100, light may be prevented from passing through the transparent bank 150 between different color converting layers 110 or being reflected and emitted by the metal layer 170.

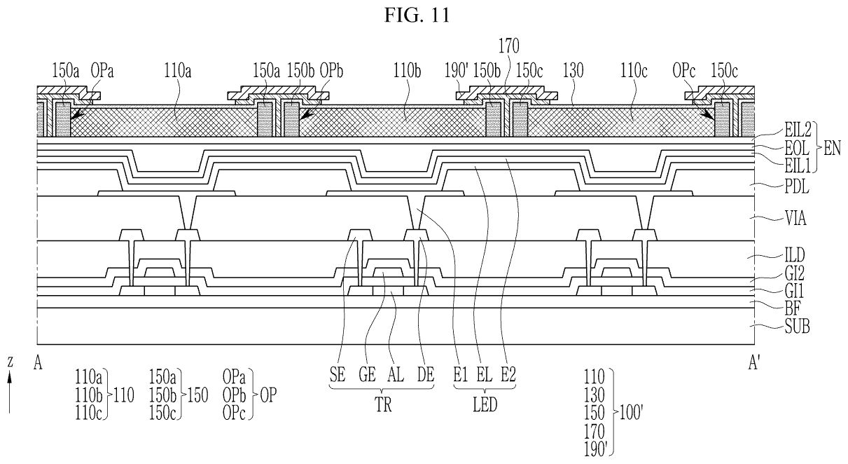

FIG. 11 is a schematic cross-sectional view illustrating a method of manufacturing a display device according to an embodiment. FIG. 11 is a schematic cross-sectional view illustrating a method of manufacturing the color converting portion according to display device of FIG. 5. In explaining FIG. 11, descriptions of substantially the same as or similar to those explained with reference to FIGS. 7 to 10 will be omitted for convenience of explanation.

Referring to FIG. 11, the anti-reflection layer 190′ may be formed on the upper surface of the metal layer 170. The anti-reflection layer 190′ may be formed to cover an upper surface of the metal layer 170. The anti-reflection layer 190′ may be formed not to cover at least a portion of a side surface of the metal layer 170. The anti-reflection layer 190′ may be formed to cover the entirety of the upper surface of the metal layer 170, and not to cover at least a portion of the side surface of the metal layer 170. For example, the anti-reflection layer 190′ may be formed not to cover the outermost side surface of the side surfaces of the metal layer 170.

The first mask and the second mask, and the first mask and the third mask may be different, and the second mask and the third mask may be the same. Accordingly, the anti-reflection layer 190′ may be formed to cover the upper surface of the metal layer 170 while forming the color converting portion 100′ using only two masks. Therefore, process efficiency may be improved, and process cost may be reduced while preventing light from being emitted between different color converting layers 110.

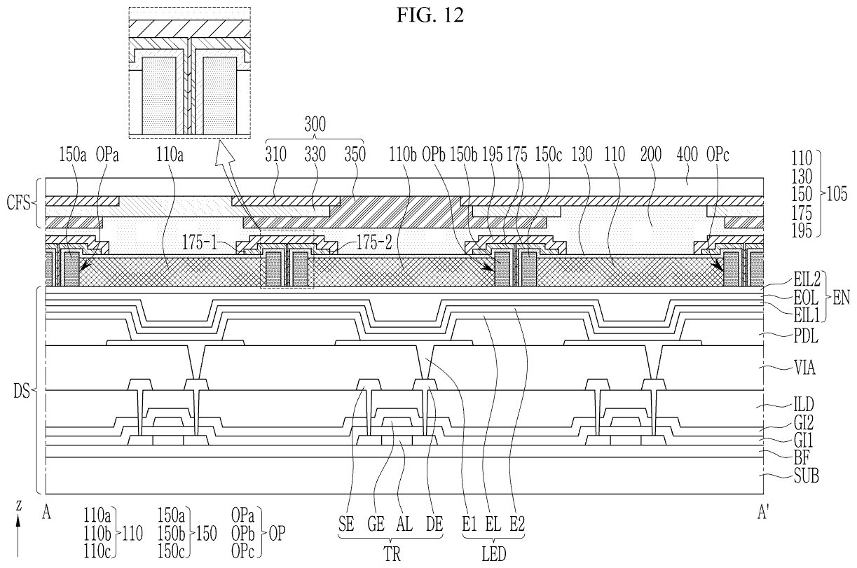

FIG. 12 is a schematic cross-sectional view of a region corresponding to approximately three pixels of a display device according to still another embodiment. In explaining FIG. 12, descriptions of substantially the same as or similar to those explained with reference to FIGS. 3 to 6 will be omitted for convenience of explanation.

Referring to FIG. 12, the color converting portion 105 may include a color converting layer 110, a capping layer 130, a bank 150, a metal layer 175, and an anti-reflection layer 195. The metal layer 175 covers the bank 150 and may be divided into two parts (e.g., a first sub-metal layer 175-1 and a second sub-metal layer 175-2) such that the two parts are separated and spaced apart from each other and some portions of the two parts may be disposed between neighboring banks 150. The two parts of the metal layer 175 cover the first sub-bank 150a and the second sub-bank 150b, respectively, and may be separated and spaced apart from each other between the first sub-bank 150a and the second sub-bank 150b. In the similar way, two parts of the metal layer 175 cover the first sub-bank 150a and the third sub-bank 150c, respectively, and may be separated and spaced apart from each other between the first sub-bank 150a and the third sub-bank 150c. In the similar way, two parts of the metal layer 175 cover the second sub-bank 150b and the third sub-bank 150c, respectively, and may be separated and spaced apart from each other between the second sub-bank 150b and the third sub-bank 150c.

The anti-reflection layer 195 may be disposed on the metal layer 175. The anti-reflection layer 195 may be disposed on an upper surface and a side surface of the metal layer 175. The anti-reflection layer 195 may cover the entirety of the metal layer 175 and fill at least a portion of a space between banks 150 neighboring each other. The anti-reflection layer 195 may fill at least a portion of a space between the first sub-bank 150a and the second sub-bank 150b. The anti-reflection layer 195 may fill at least a portion of a space between the first sub-bank 150a and the third sub-bank 150c. The anti-reflection layer 195 may fill at least a portion of a space between the second sub-bank 150b and the third sub-bank 150c. The anti-reflection layer 195 may fill at least a portion of a space between the two parts of the metal layers 175, which are separated and spaced apart from each other. The anti-reflection layer 195 may completely fill a space between the two parts of the metal layers 175, which are separated and spaced apart from each other.

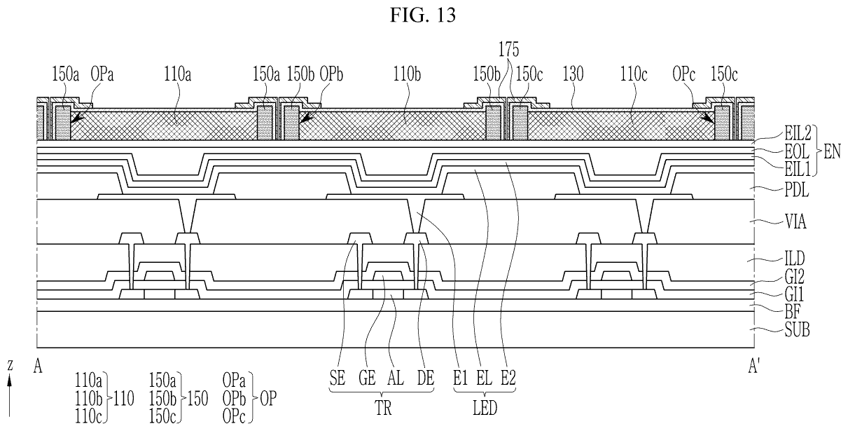

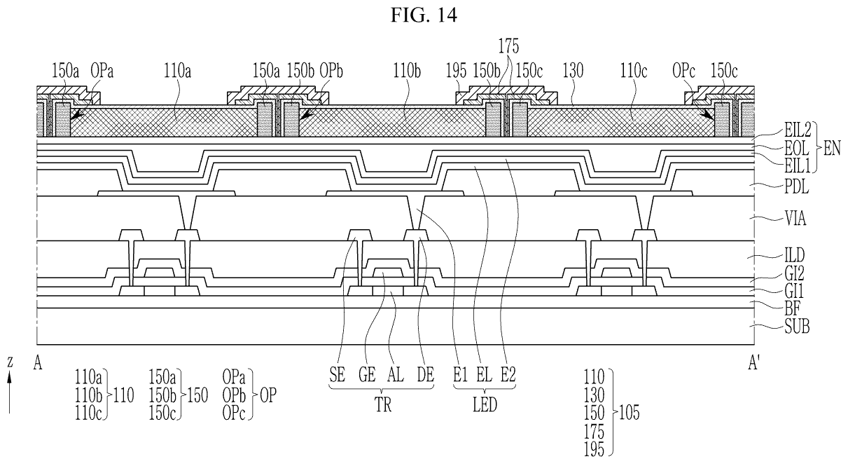

FIG. 13 and FIG. 14 are schematic cross-sectional views illustrating a method of manufacturing a display device according to an embodiment. FIG. 13 and FIG. 14 are schematic cross-sectional views illustrating a method of manufacturing a display device of FIG. 12. In explaining FIG. 13 and FIG. 14, descriptions of substantially the same as or similar to those explained with reference to FIGS. 7 to 11 will be omitted for convenience of explanation.

Referring to FIG. 13, a metal layer 175 may be formed on the bank 150. The metal layer 175 may be formed on an upper surface and a side surface of the bank 150. The metal layer 175 may be formed through a second mask. The metal layer 175 may be formed by applying metal on the bank 150 or the capping layer 130 and then patterning it using the second mask. The metal layer 175 may cover the first sub-bank 150a, the second sub-bank 150b, and the third sub-bank 150c. The metal layer 175 may be formed to be separated and spaced between neighboring banks 150. The metal layer 175 may be formed to be separated and spaced between the first sub-bank 150a and the second sub-bank 150b. The metal layer 175 may be formed to be separated and spaced between the first sub-bank 150a and the third sub-bank 150c. The metal layer 175 may be formed to be separated and spaced between the second sub-bank 150b and the third sub-bank 150c. The metal layer 175 may be formed to fill at least a portion of spaces between the first sub-bank 150a and the second sub-bank 150b, between the first sub-bank 150a and the third sub-bank 150c, and between the second sub-bank 150b and the third sub-bank 150c.

Referring to FIG. 14, an anti-reflection layer 195 may be formed on the metal layer 175. Accordingly, a color converting portion 105 including a color converting layer 110, a capping layer 130, a bank 150, a metal layer 175, and an anti-reflection layer 195 may be formed. The anti-reflection layer 195 may be formed on an upper surface and a side surface of the metal layer 175. The anti-reflection layer 195 may be formed using a third mask. The anti-reflection layer 195 may be formed by applying a material contained in the color filter layer on at least one of the color converting layer 110, the capping layer 130, and the metal layer 175, and patterning it using the third mask. The anti-reflection layer 195 may be formed to cover the entirety of the metal layer 175. The anti-reflection layer 195 may be formed to fill a space between the metal layers 175 that are separated and spaced apart from each other. The anti-reflection layer 195 may be formed to partially cover the color converting layer 110.

The second mask for forming the metal layer 175 and the third mask for forming the anti-reflection layer 195 may be different masks.

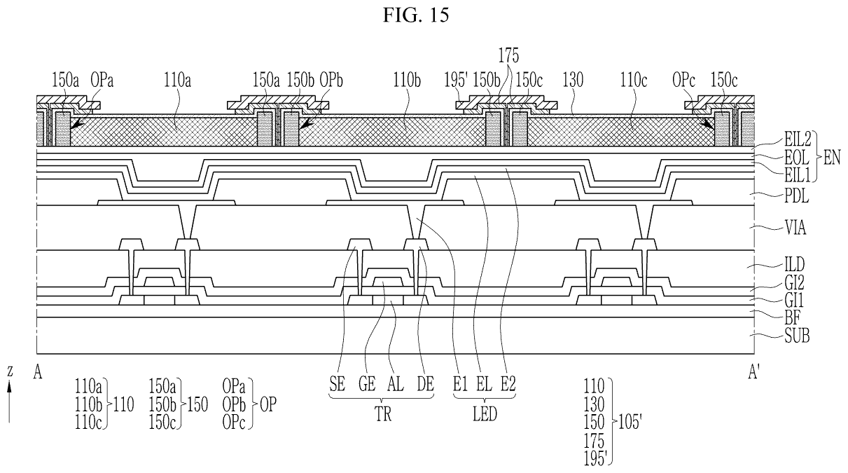

FIG. 15 is a schematic cross-sectional view illustrating a method of manufacturing a display device according to an embodiment. In explaining FIG. 15, descriptions of substantially the same as or similar to those explained with reference to FIGS. 7 to 11, FIG. 13 and FIG. 14 will be omitted for convenience of explanation.

Referring to FIG. 15, the anti-reflection layer 190′ may be formed to cover an upper surface of the metal layer 175. Accordingly, a color converting portion 105′ including a color converting layer 110, a capping layer 130, a bank 150, a metal layer 175, and an anti-reflection layer 195′ may be formed. The anti-reflection layer 195′ may be formed not to cover at least a portion of a side surface of the metal layer 175. The anti-reflection layer 195′ may be formed to cover the entirety of the upper surface of the metal layer 175, and not to cover at least a portion of the side surface of the metal layer 175. For example, the anti-reflection layer 195′ may be formed not to cover the outermost side surface of the side surfaces of the metal layer 175. The anti-reflection layer 195′ may be formed to fill a space between the metal layers 175 that are separated and spaced apart from each other. The second mask and the third mask may be the same mask.

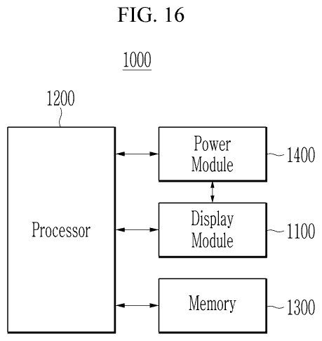

FIG. 16 is a block diagram of an electronic device according to an embodiment.

The electronic device 1000 may include electronic components and a display device. The display device may include a display device as described with reference to FIGS. 1 to 15. The display device may include a substrate, a light emitting element disposed on the substrate, a bank disposed on the light emitting element and defining therein an opening overlapping the light emitting element, a color converting layer disposed on the light emitting element and disposed within the opening, and a metal layer disposed on the bank. The light emitting elements may include a first light emitting element, a second light emitting element, and a third light emitting element that are adjacent to each other. The openings may include a first opening, a second opening and a third opening, and the first opening, the second opening and the third opening may overlap the first light emitting element, the second light emitting element and the third light emitting element, respectively. The color converting layer may include a first color converting layer, a second color converting layer, and a third color converting layer, and the first color converting layer, the second color converting layer, and the third color converting layer may be disposed in the first opening, the second opening, and the third opening, respectively.

The banks may be separated from each other between color converting layers different from each other. The bank may include a first sub-bank and a second sub-bank, which are separated from each other between the first color converting layer and the second color converting layer. The bank may include a first sub-bank and a third sub-bank, which are separated from each other between the first color converting layer and the third color converting layer. The bank may include a second sub-bank and a third sub-bank, which are separated from each other between the second color converting layer and the third color converting layer. The first sub-bank may surround the first color converting layer, the second sub-bank may surround the second sub-bank, and the third sub-bank may surround the third color converting layer.

The metal layers may be separated from each other to be disposed between neighboring banks. The metal layer may be disposed between the first sub-bank and the second sub-bank, between the first sub-bank and the third sub-bank, and between the second sub-bank and the third sub-bank. The metal layer covers the first sub-bank and the second sub-bank, and may fill at least a portion of a space between the first sub-bank and the second sub-bank. The metal layer covers the first sub-bank and the third sub-bank, and may fill at least a portion of a space between the first sub-bank and the third sub-bank. The metal layer covers the second sub-bank and the third sub-bank, and may fill at least a portion of a space between the second sub-bank and the third sub-bank. The metal layers may be spaced apart from each other between the first sub-bank and the second sub-bank. The metal layers may be spaced apart from each other between the first sub-bank and the third sub-bank. The metal layers may be spaced apart from each other between the second sub-bank and the third sub-bank.

Referring to FIG. 16, the electronic device 1000 may include electronic components such as display module 1100, processor 1200, memory 1300, power module 1400, etc.

The display module 1100 may include a display panel, a driver, etc. The display panel may include pixels displaying images and may provide a display screen. The driver may process and supply signals to the display panel for displaying images on the display screen of the display panel. The driver may be provided in a form of IC chip.

The processor 1200 may include at least one of a central processing unit (CPU), an application processor (AP), a graphic processing unit (GPU), a communication processor (CP), an image signal processor (ISP), and a controller.

The memory 1300 may store data information necessary for the operation of processor 1200 or display module 1100. When the processor 1200 executes an application stored in the memory 1300, an image data signal and/or an input control signal are transmitted to the display module 1100, and the display module 1100 may process the received signals and display an image through the display screen.

The power module 1400 may include a power supplying module, such as a power adaptor or battery device, and a power conversion module converting power supplied by the power supplying module to generate power required for the operation of the electronic device 1000.

At least one of the components of the electronic device 1000 described above may be included in a display device according to embodiments. Additionally, some of the individual modules functionally included within a module may be included in the display device, and others may be provided separately from the display device. For example, the display device may include the display module 1100, and the processor 1200, memory 1300, and power module 1400 may be provided in a form of other devices within the electronic device 1000 other than the display device.

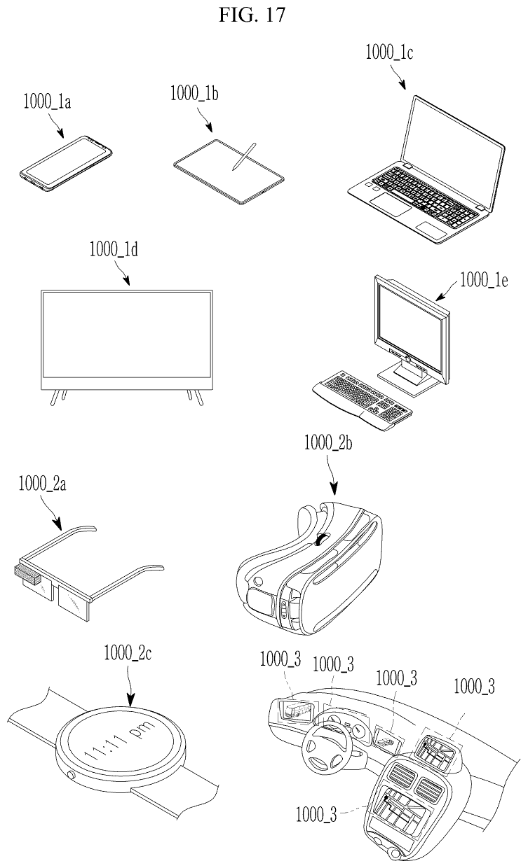

FIG. 17 is a schematic drawing of electronic devices according to various embodiments.

Referring to FIG. 17, various electronic devices to which a display device according to embodiments of the present disclosure is applied may include electronic devices for displaying images, such as a smart phone (1000_1a), a tablet PC (1000_1b), a laptop (1000_1c), a TV (1000_1d), a desk monitor (1000_1e), etc. In addition, the electronic device may include a wearable electronic device including a display module such as smart spectacles (1000_2a), a head mounted display (1000_2b), a smart watch (1000_2c), an electronic device for a vehicle including a display module or display device such as a CID (Center Information Display) arranged on an instrument panel, center fascia, or dashboard of a vehicle (1000_3), and the like.

Although the embodiments of the present disclosure have been described in detail above, the scope of the present disclosure is not limited thereto, and various modifications and improvements may be made by those skilled in the art using the basic concept of the present disclosure defined in the following claims, and they fall within the scope of the present disclosure.

### DESCRIPTION OF SYMBOLS

100, 100′, 105, 105′: color converting portion, 110: color converting layer
110a: first color converting layer
110b: second color converting layer
110c: third color converting layer
130: capping layer
150: bank
150a: first sub-bank
150b: second sub-bank
150c: third sub-bank
170, 175: metal layer
190, 190′, 195, 195′: anti-reflection layer
200: third insulation layer
300: color filter layer
310: first color filter layer
330: second color filter layer
350: third color filter layer
400: upper substrate
OP: opening OPa: first opening
OPb: second opening OPc: third opening

What is claimed is:

1. A display device comprising:
a substrate;
a first light emitting element and a second light emitting element disposed on the substrate and adjacent to each other;
an encapsulation layer disposed on the first light emitting element and the second light emitting element;
a bank disposed on the encapsulation layer and defining therein a first opening and a second opening overlapping the first light emitting element and the second light emitting element, respectively, in a plan view;
a first color converting layer and a second color converting layer disposed on the encapsulation layer and disposed in the first opening and the second opening, respectively; and
a metal layer disposed on the bank,
wherein:
the bank comprises a first sub-bank and a second sub-bank, which are separated from each other and disposed between the first color converting layer and the second color converting layer; and
the metal layer comprises a portion disposed between the first sub-bank and the second sub-bank.

2. The display device of claim 1, wherein:
the first sub-bank surrounds the first color converting layer in the plan view; and
the second sub-bank is spaced apart from the first sub-bank and surrounds the second color converting layer in the plan view.

3. The display device of claim 2, wherein
the metal layer covers the first sub-bank and the second sub-bank, and fills at least a portion of a space between the first sub-bank and the second sub-bank.

4. The display device of claim 3, further comprising
an anti-reflection layer disposed on the metal layer,
wherein the anti-reflection layer covers an entirety of the metal layer.

5. The display device of claim 2, wherein:
the metal layer includes a first sub-metal layer and a second sub-metal layer, which cover the first sub-bank and the second sub-bank, respectively, and are spaced apart from each other between the first sub-bank and the second sub-bank.

6. The display device of claim 5, further comprising
an anti-reflection layer disposed on the metal layer,
wherein the anti-reflection layer covers an entirety of the metal layer and fills at least a portion of a space between the first sub-metal layer and the second sub-metal layer.

7. The display device of claim 1, further comprising
an anti-reflection layer disposed on the metal layer,
wherein the metal layer partially covers the first color converting layer and the second color converting layer.

8. The display device of claim 7, wherein
the anti-reflection layer covers an upper surface and a side surface of the metal layer, and partially covers the first color converting layer and the second color converting layer.

9. The display device of claim 7, wherein
the anti-reflection layer covers an upper surface of the metal layer and does not cover a side surface of the metal layer.

10. The display device of claim 1, further comprising:
a capping layer disposed between the bank and the metal layer; and
a color filter layer disposed on the bank, the first color converting layer, and the second color converting layer.

11. The display device of claim 10, wherein
the capping layer covers the first color converting layer and the second color converting layer.

12. An electronic device comprising a display device and electronic components,
wherein the display device comprises:
a substrate;
a first light emitting element and a second light emitting element disposed on the substrate and adjacent to each other;
a bank disposed on the first light emitting element and the second light emitting element and defining therein a first opening and a second opening overlapping the first light emitting element and the second light emitting element, respectively, in a plan view;
a first color converting layer and a second color converting layer disposed on the first light emitting element and the second light emitting element, and disposed in the first opening and the second opening, respectively; and
a metal layer disposed on the bank,
wherein:
the bank comprises a first sub-bank and a second sub-bank, which are separated from each other and disposed between the first color converting layer and the second color converting layer; and
the metal layer is disposed between the first sub-bank and the second sub-bank.

13. The electronic device of claim 12, wherein:
the first sub-bank surrounds the first color converting layer in the plan view;
the second sub-bank is spaced apart from the first sub-bank and surrounds the second color converting layer in the plan view; and
the metal layer covers the first sub-bank and the second sub-bank, and fills at least a portion of a space between the first sub-bank and the second sub-bank.

14. The electronic device of claim 12, wherein
the first sub-bank surrounds the first color converting layer in the plan view; and
the second sub-bank is spaced apart from the first sub-bank and surrounds the second color converting layer in the plan view; and
the metal layer includes a first sub-metal layer and a second sub-metal layer, which cover the first sub-bank and the second sub-bank, respectively, and are spaced apart from each other between the first sub-bank and the second sub-bank.

15. A method of manufacturing a display device, comprising:
forming a first light emitting element and a second light emitting element adjacent to each other on a substrate;
forming an encapsulation layer on the first light emitting element and the second light emitting element;
forming a bank including a first sub-bank defining therein a first opening overlapping the first light emitting element and a second sub-bank separated from the first sub-bank and defining therein a second opening overlapping the second light emitting element in a plan view;
forming a first color converting layer and a second color converting layer disposed in the first opening and the second opening, respectively;
forming a metal layer disposed on the bank and disposed between the first sub-bank and the second sub-bank; and
forming an anti-reflection layer on the metal layer.

16. The method of claim 15, wherein:
the bank is formed through a first mask;
the metal layer is formed through a second mask; and
the anti-reflection layer is formed through a third mask.

17. The method of claim 16, wherein
the second mask and the third mask are a same mask.

18. The method of claim 15, wherein
the metal layer fills at least a portion of a space between the first sub-bank and the second sub-bank.

19. The method of claim 15, wherein
the metal layer includes a first sub-metal layer and a second sub-metal layer, which cover the first sub-bank and the second sub-bank, respectively, and are spaced apart from each other between the first sub-bank and the second sub-bank.

20. The method of claim 15, further comprising forming a capping layer on the bank and the color converting layer.
